(19) United States
(12) Patent Application Publication
(10) Pub. No.: US 2025/0294906 A1
(43) Pub. Date: Sep. 18, 2025

(54) SEMICONDUCTOR DEVICE AND METHOD OF FABRICATING THE SAME

(71) Applicant: WUHAN XINXIN SEMICONDUCTOR MANUFACTURING CO., LTD., Wuhan (CN)

(72) Inventors: Liliang GU, Wuhan (CN); Danqing WEI, Wuhan (CN); Qingwei LUO, Wuhan (CN)

(21) Appl. No.: 19/030,672

(22) Filed: Jan. 17, 2025

(30) Foreign Application Priority Data
Mar. 13, 2024 (CN) 202410288458.5

(51) Int. Cl. H10F 39/00

(52) U.S. Cl. CPC H10F 39/807; H10F 39/011; H10F 39/811

(57) ABSTRACT

The present invention provides a semiconductor device and a method of fabricating it. The semiconductor device includes: a substrate having opposing first and second surfaces; trench isolations extending from the first surface of the substrate into the substrate, each of the trench isolations comprising a first conductive layer insulated from the substrate; an insulating dielectric layer formed on the first surface of the substrate and the trench isolations; first openings, second openings and third openings, the first and second openings situated in the insulating dielectric layer, the first openings exposing the substrate, the second openings exposing the first conductive layer in the trench isolations, the third openings extending through the substrate; and a second conductive layer filling the first openings providing first electrodes, filling the second openings and extending outside the second openings providing a metal grid, filling the third openings providing an electrical leading-out structure.

### CROSS-REFERENCES TO RELATED APPLICATION

This application claims the priority of Chinese patent application number 202410288458.5, filed on Mar. 13, 2024, the entire contents of which are incorporated herein by reference.

### TECHNICAL FIELD

The present invention relates to the field of integrated circuit fabrication and, in particular, to a semiconductor device and method of fabricating the same.

### BACKGROUND

Most existing single-photon avalanche diodes (SPADs) employ a vertical design, in which two electrodes are arranged on the front side. In order to enable vertical breakdown of the diode, the two electrodes must be isolated, or spaced apart at a sufficient distance, from each other. As single-photon detectors develop, increasingly larger pixel arrays are desired. This means area shrinkage of diodes at a given window size. For the design with two electrodes arranged on the front side, since it would be impossible to reduce the spacing between the two electrodes as much as desired, its fill factor is typically not high enough, affecting the performance of a detector employing the design. In order to overcome this, it has been proposed to arrange the two electrodes respectively on the opposing front and back sides. Specifically, the substrate may be thinned from the backside to a desired thickness, and a hole may be formed in the substrate. Aluminum may be then filled in the hole to form the backside (first) electrode. Additionally, the aluminum in multiple such first electrodes may constitute a metal grid, which can reduce optical crosstalk.

However, due to poor hole-filling properties of aluminum, if the hole has a relatively large depth-to-width ratio, a void or voids may be present after filling, which may lead to electrical connection issues, such as increased contact resistance between the first electrode and the substrate, or even an open circuit in worse cases. Therefore, in order to ensure good filling of aluminum in the hole, the hole is desired to have a sufficiently large width (e.g., >0.65 μm). However, this would be undesirable for an optical path in a pixel cell incorporating the diode. Specifically, as the hole is typically formed at a corner of the pixel cell, a larger hole width will lead to a larger light shielding area of the first electrode and hence a reduced light absorbing area of the pixel cell. Consequently, light absorption of the diode in the pixel cell, and hence the photon detection efficiency of a device incorporating the pixel cell, will be affected, in particular at a chip size reduced to 5 μm or less. Further, the metal grid made of aluminum tends to be reflective and have a large width (e.g., as large as 1.25 μm). These would additionally reduce light shining into the pixel cell, leading to a further decrease in the device's photon detection efficiency.

Therefore, there is an urgent need for an improved first electrode, which does not adversely affect the reliability and optical performance of a device in which it is incorporated.

### SUMMARY

It is an objective of the present invention to provide a semiconductor device with improved reliability and optical performance and a method of fabricating such a device.

To this end, the present invention provides a semiconductor device including: a substrate having opposing first and second surfaces; trench isolations extending from the first surface of the substrate into the substrate, each of the trench isolations including a first conductive layer insulated from the substrate; an insulating dielectric layer formed on the first surface of the substrate and the trench isolations; first openings, second openings and third openings, the first and second openings situated in the insulating dielectric layer, the first openings exposing the substrate, the second openings exposing the first conductive layer in the trench isolations, the third openings extending through the substrate; and a second conductive layer filling the first, second and third openings and extending outside the second openings, the second conductive layer that fills the first openings providing first electrodes, the second conductive layer that fills the second openings and extends outside the second openings providing a metal grid, the second conductive layer that fills the third openings providing an electrical leading-out structure.

Optionally, the trench isolations may be arranged in a first direction and a second direction into an array, wherein the trench isolations arranged in the first direction cross the trench isolations arranged in the second direction at intersections, and wherein each of the intersections is provided at its four corners with respective ones of the first electrodes.

Optionally, the metal grid may be arranged in a first direction and a second direction into an array, wherein a projection of the metal grid within and/or outside the second openings on the first surface of the substrate at least partially overlaps projections of the trench isolations on the first surface of the substrate.

Optionally, the projection of the metal grid within and/or outside the second openings on the first surface of the substrate may be encompassed by the projections of the trench isolations on the first surface of the substrate.

Optionally, the first conductive layer may be made of the same material as the second conductive layer.

Optionally, second electrodes may be formed on the second surface of the substrate.

Optionally, the first electrodes may be electrically connected to the substrate and the metal grid is electrically connected to the first conductive layer in the trench isolations.

Optionally, the first openings may be isolated from the second openings by the insulating dielectric layer.

Optionally, the first openings may be brought into communication with the second openings, and the first electrodes and the metal grid are both electrically connected to both the substrate and the first conductive layer.

Optionally, the third openings may include trenches and first holes, and wherein the first openings, the second openings and the trenches are formed in a single process.

The present invention also provides a method of fabricating a semiconductor device, which includes: providing a substrate having opposing first and second surfaces; forming trench isolations extending from the first surface of the substrate into the substrate, each of the trench isolations including a first conductive layer insulated from the substrate; forming an insulating dielectric layer on the first surface of the substrate and the trench isolations; forming first openings, second openings and third openings in a surface of the insulating dielectric layer away from the substrate, the first and second openings situated in the insulating dielectric layer, the first openings exposing the substrate, the second openings exposing the first conductive layer in the trench isolations, the third openings extending through the substrate; and depositing a second conductive layer in the first, second and third openings, the second conductive layer that fills the first openings providing first electrodes, the second conductive layer that fills the second openings and extends outside the second openings providing a metal grid, the second conductive layer that fills the third openings providing an electrical leading-out structure.

Optionally, the second conductive layer may be formed using a process including:
forming a conductive material in the first, second and third openings and on a surface of the insulating dielectric layer; and
removing part of the conductive material above the surface of the insulating dielectric layer by patterning, with the conductive material in the first, second and third openings and above the second openings being retained as the second conductive layer.

Optionally, the method may further include, after the second conductive layer is formed,
forming pads on the electrical leading-out structure, which are electrically connected to the electrical leading-out structure.

Optionally, the third openings may include trenches and first holes, and wherein the first openings, the second openings and the trenches are formed in a single process.

Optionally, the trench isolations may be arranged in a first direction and a second direction into an array, wherein the trench isolations arranged in the first direction cross the trench isolations arranged in the second direction at intersections, and wherein each of the intersections is provided at its four corners with respective ones of the first electrodes.

Optionally, the metal grid may be arranged in a first direction and a second direction into an array, wherein a projection of the metal grid within and/or outside the second openings on the first surface of the substrate at least partially overlaps projections of the trench isolations on the first surface of the substrate.

Optionally, the projection of the metal grid within and/or outside the second openings on the first surface of the substrate may be encompassed by the projections of the trench isolations on the first surface of the substrate.

Optionally, the first conductive layer may be made of the same material as the second conductive layer.

Optionally, the first openings are isolated from the second openings by the insulating dielectric layer, the first electrodes may be electrically connected to the substrate and the metal grid is electrically connected to the first conductive layer in the trench isolations.

Optionally, the first openings may be brought into communication with the second openings, and the first electrodes and the metal grid are both electrically connected to both the substrate and the first conductive layer.

The present invention provides the following benefits over the prior art:
1. It provides a semiconductor device including: a substrate having opposing first and second surfaces; trench isolations extending from the first surface of the substrate into the substrate, each of the trench isolations including a first conductive layer insulated from the substrate; an insulating dielectric layer formed on the first surface of the substrate and the trench isolations; first openings, second openings and third openings, the first and second openings situated in the insulating dielectric layer, the first openings exposing the substrate, the second openings exposing the first conductive layer in the trench isolations, the third openings extending through the substrate; and a second conductive layer filling the first, second and third openings and extending outside the second openings, the second conductive layer that fills the first openings providing first electrodes, the second conductive layer that fills the second openings and extends outside the second openings providing a metal grid, the second conductive layer that fills the third openings providing electrical leading-out structure. Thus, the semiconductor device can provide higher reliability and optical performance.
2. It provides a method of fabricating a semiconductor device, which includes: providing a substrate having opposing first and second surfaces; forming trench isolations extending from the first surface of the substrate into the substrate, each of the trench isolations including a first conductive layer insulated from the substrate; forming an insulating dielectric layer on the first surface of the substrate and the trench isolations; forming first, second and third openings in a surface of the insulating dielectric layer away from the substrate, the first and second openings situated in the insulating dielectric layer, the first openings exposing the substrate, the second openings exposing the first conductive layer in the trench isolations, the third openings extending through the substrate; and depositing a second conductive layer in the first, second and third openings, the second conductive layer that fills the first openings providing first electrodes, the second conductive layer that fills the second openings and extends outside the second openings providing a metal grid, the second conductive layer that fills the third openings providing an electrical leading-out structure. A semiconductor device with improved reliability and optical performance is obtainable according to this method.

### BRIEF DESCRIPTION OF THE DRAWINGS

FIG. 1 shows a schematic top view of a semiconductor device according to an embodiment of the present invention.

FIG. 2 shows a schematic top view of a semiconductor device according to another embodiment of the present invention.

FIG. 3 shows a schematic longitudinal cross-sectional view of the semiconductor device of FIG. 1 taken along AA′.

FIG. 4 shows a schematic longitudinal cross-sectional view of the semiconductor device of FIG. 2 taken along CC′.

FIG. 5 shows a schematic longitudinal cross-sectional view of the semiconductor device of FIG. 1 taken along BB′ and a schematic longitudinal cross-sectional view of the semiconductor device of FIG. 2 taken along DD′.

FIG. 6 shows a flowchart of a method of fabricating a semiconductor device according to an embodiment of the present invention.

In FIGS. 1 to 6,
11 denotes a first substrate; 111, a first interlayer dielectric layer; 112, a first metal interconnect; 113, a shallow trench isolation; 12, a trench isolation; 120, a deep trench; 121, a first insulating dielectric layer; 122, a first conductive layer; 13, a second insulating dielectric layer; 14, a first opening; 15, a second opening; 16, a third opening; 161, a trench; 162, a first hole; 163, a second hole; 17, a second conductive layer; 18, a third insulating dielectric layer; 19, a pad; 21, a second substrate; 22, a second interlayer dielectric layer; and 221, a second metal interconnect.

### DETAILED DESCRIPTION

Objectives, advantages and features of the present invention will become more apparent upon reading the following more detailed description of semiconductor devices and methods of fabricating the same proposed herein in conjunction with the accompanying drawings. Note that the figures are provided in a very simplified form not necessarily drawn to exact scale for the only purpose of helping explain embodiments of the invention disclosed herein in a more convenient and clearer way.

In one embodiment of the present invention, there is provided a semiconductor device including: a substrate having opposing first and second surfaces; trench isolations extending from the first surface of the substrate into the substrate, each of the trench isolations including a first conductive layer insulated from the substrate; an insulating dielectric layer formed on the first surface of the substrate and the trench isolations; first openings, second openings and third openings, the first and second openings situated in the insulating dielectric layer, the first openings exposing the substrate, the second openings exposing the first conductive layer in the trench isolations, the third openings extending through the substrate; and a second conductive layer filling the first, second and third openings and extending outside the second openings, the second conductive layer that fills the first openings providing first electrodes, the second conductive layer that fills the second openings and extends outside the second openings providing a metal grid, the second conductive layer that fills the third openings providing an electrical leading-out structure.

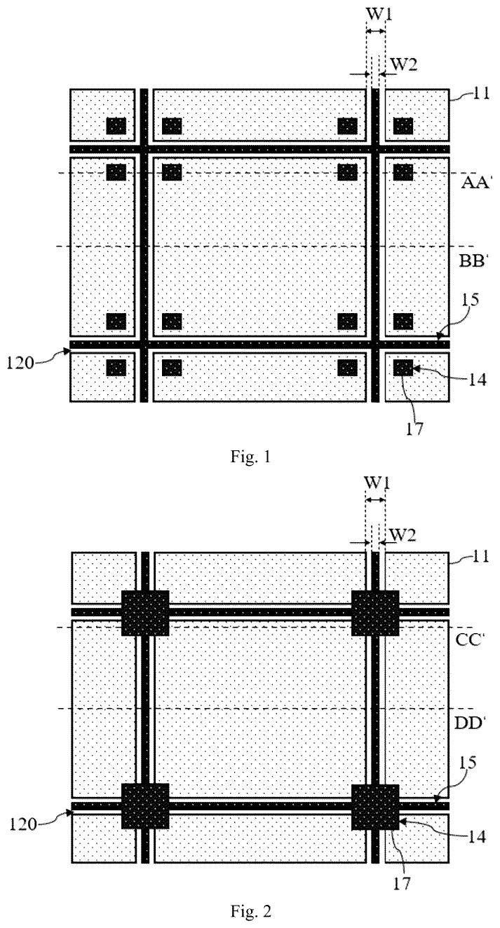

The semiconductor device of this embodiment will be described in greater detail below with reference to FIGS. 1 to 5. FIGS. 1 and 2 are schematic partial views of the semiconductor device. As a non-limiting example, the embodiments shown in FIGS. 1 to 5 are described in the context of use in an image sensor of a three-dimensional (3D) integrated circuit (IC).

The device includes a substrate (referred to hereinafter as the first substrate 11, in order to be distinguished from the second substrate) with opposing first and second surfaces.

A first interlayer dielectric layer 111 may be formed on the second surface of the first substrate 11. In the first interlayer dielectric layer 111 may be formed first metal interconnects 112, as well as other functional structures such as transistors or micro-electro-mechanical systems (MEMS's, e.g., diaphragms, electrodes, etc.) Thus, a device wafer is provided. The type of the device wafer may depend on the functionality of the device being fabricated. Alternatively, the first substrate 11 may be a die obtained by dicing such a wafer, without limiting the present application in any sense.

In one embodiment, the semiconductor device may further include a second substrate 21 bonded to the first substrate 11. In this case, the first substrate 11 may be bonded to the second substrate 21 at the second surface of the first substrate 11.

The second substrate 21 includes opposing first and second surfaces. A second interlayer dielectric layer 22 may be formed on the second surface of the second substrate 21, and second metal interconnects 221 may be formed in the second interlayer dielectric layer 22. The side of the first interlayer dielectric layer 111 away from the first substrate 11 may be bonded to the side of the second interlayer dielectric layer 22 away from the second substrate 21, the first metal interconnects 112 are electrically connected to the second metal interconnects 221. The second interlayer dielectric layer 22 may also contain other functional structures, such as transistors or MEMS's (e.g., diaphragms, electrodes, etc.), thus, another device wafer is provided. The type of the device wafer may depend on the functionality of the device being fabricated. Alternatively, the second interlayer dielectric layer 22 may not contain any functional structures, and may serve as a carrier wafer without any device functions. Still alternatively, the second substrate 21 may be a die obtained by dicing such a wafer, without limiting the present application in any sense.

The first surface(s) of the first substrate 11 and/or the second substrate 21 may be defined as its/their backside(s), and the second surface(s) as front side(s). Alternatively, the first surface(s) of the first substrate 11 and/or the second substrate 21 may be defined as its/their front side(s), and the second surface(s) as backside(s).

The first substrate 11 and/or the second substrate 21 may be fabricated from any suitable substrate material known to those skilled in the art, such as glass, ceramic, a semiconductor material or the like. It may be at least one of the following materials: silicon, germanium, silicon germanium, silicon carbide, silicon germanium carbide, indium arsenide, gallium arsenide and indium phosphide. Alternatively, the first substrate 11 and the second substrate 21 may be silicon-on-insulator (SOI) substrates.

The device also includes trench isolations 12 extending from the first surface of the first substrate 11 into the first substrate 11, each of the trench isolations 12 includes a first conductive layer 122, the first conductive layer 122 is insulated from the first substrate 11.

The first conductive layer 122 may be insulated from the first substrate 11 by a first insulating dielectric layer 121.

In the first substrate 11 may be formed deep trenches 120 extending from the first surface of the first substrate 11 into the first substrate 11. The first insulating dielectric layer 121 may line inner wall surfaces of the deep trenches 120, and the first conductive layer 122 may fill the deep trenches 120.

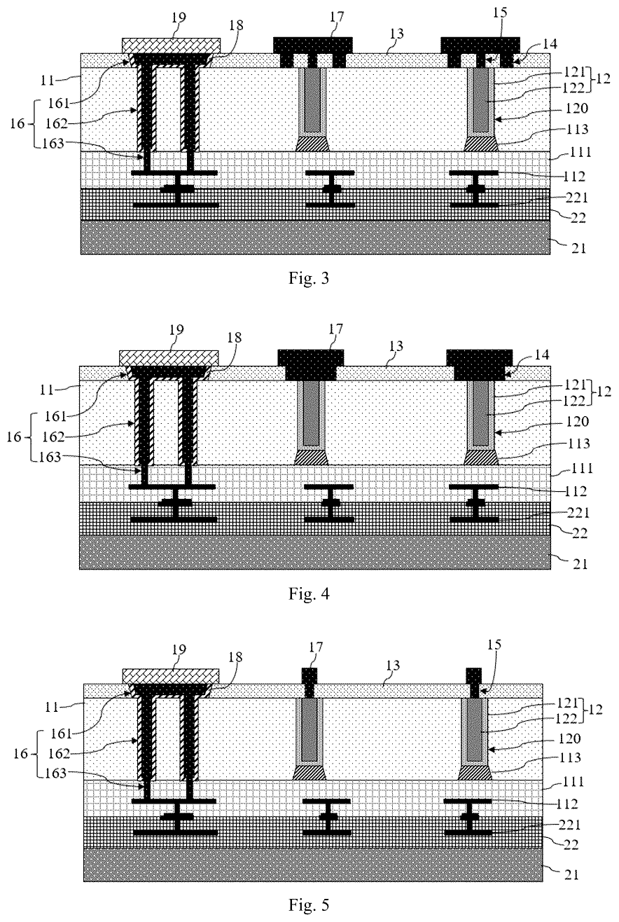

Top surfaces of the trench isolations 12 may be flush with the first surface of the first substrate 11 (as shown in FIGS. 3 to 5). Alternatively, the top surfaces of the trench isolations 12 may be higher or lower than the first surface of the first substrate 11. The first insulating dielectric layer 121 may also extend on the first surface of the first substrate 11.

A second insulating dielectric layer 13 is formed on the first surface of the first substrate 11 and the trench isolations 12.

The first insulating dielectric layer 121 and/or the second insulating dielectric layer 13 may each be any electrically insulating material known in the art. For example, it may include at least one of silicon oxide and high-k dielectrics with a dielectric constant (k) greater than 3.9. The first insulating dielectric layer 121 and/or the second insulating dielectric layer 13 may each be a single layer or a stack of at least two layers (e.g., one silicon oxide layer and one high-k dielectric layer). Other material(s) may also be present between the first insulating dielectric layer 121 and/or the second insulating dielectric layer 13 and the first substrate 11.

A high-k dielectric can enable the first insulating dielectric layer 121 to provide enhanced insulation.

First openings 14 and second openings 15 are formed in the second insulating dielectric layer 13. The first substrate 11 is exposed in the first openings 14, and the first conductive layer 122 in the trench isolations 12 is exposed in the second openings 15. The third openings 16 extend through the second insulating dielectric layer 13 and the first substrate 11.

A second conductive layer 17 fills the first openings 14, the second openings 15 and the third openings 16 and extends outside the second openings 15. The second conductive layer 17 that fills the first openings 14 provides first electrodes. The second conductive layer 17 that fills the second openings 15 and extends outside the second openings 15 provides a metal grid. The second conductive layer 17 that fills the third openings 16 provides an electrical leading-out structure. In other embodiments, in addition to filling the first openings 14, the second conductive layer 17 may also extend outside the first openings 14.

Preferably, the deep trenches 120, the first openings 14 and the second openings 15 may be located in a pixel area, and the third openings 16 may be located in a peripheral area which is peripheral to the pixel area. The third openings 16 are not shown in the schematic diagrams of FIGS. 1 and 2.

The first openings 14, the second openings 15 and the third openings 16 may also extend through any material between the second insulating dielectric layer 13 and the first surface of the first substrate 11, if present. For example, the first insulating dielectric layer 121 is formed on the first surface of the first substrate 11 and the second insulating dielectric layer 13 in turn on the first insulating dielectric layer 121. In this case, the first openings 14, the second openings 15 and the third openings 16 may also extend through the first insulating dielectric layer 121.

The trench isolations 12 may be arranged in both first and second directions into an array. Moreover, the trench isolations 12 arranged in the first direction may cross the trench isolations 12 arranged in the second direction at intersections.

As shown in FIGS. 1 and 3, the first electrodes may be located at corners of the intersections. Additionally, the first openings 14 may be isolated from the second openings 15 by the second insulating dielectric layer 13, and the first electrodes may be electrically connected to the first substrate 11 and the metal grid may be electrically connected to the first conductive layer 122 in the trench isolations 12. Alternatively, as shown in FIGS. 2 and 4, with the first electrodes being located at corners of the intersections, the first openings 14 may be brought into communication with the second openings 15, and the first electrodes and the metal grid may be both electrically connected to both the first substrate 11 and the first conductive layer 122.

The metal grid may be arranged in the first and second directions into an array. A projection of the metal grid within or outside the second openings 15 on the first surface of the first substrate 11 may at least partially overlap projections of the trench isolations 12 on the first surface of the first substrate 11. Preferably, the projection of the metal grid within and/or outside the second openings 15 on the first surface of the first substrate 11 may be encompassed by the projections of the trench isolations 12 on the first surface of the first substrate 11. In particular, in a cross-section perpendicular to the first surface of the first substrate 11, the deep trenches 120 may have a width W1, the second openings 15 may have a width W2, and the metal grid outside the second openings 15 may have a width W3 (not shown). Additionally, W2 or W3 may be not greater than W1, i.e., W3≤W1 or W2≤W1. In other embodiments, W2 or W3 may be greater than W1.

Devices may be formed in the first substrate 11 surrounded by adjacent trench isolations 12 arranged in the first direction and adjacent trench isolations 12 arranged in the second direction. The adjacent two trench isolations 12 arranged in the first direction and the adjacent two trench isolations 12 arranged in the second direction may delimit a region having any shape in a transverse cross-section parallel to the first surface of the first substrate 11. Examples of the shape may include, but are not limited to, quadrilateral, hexagonal, octagonal and circular shapes.

The first openings 14 and/or the second openings 15 may have any shape in a transverse cross-section parallel or perpendicular to the first surface of the first substrate 11. Examples of the shape may include, but are not limited to, quadrilateral, hexagonal, octagonal and circular shapes.

The trench isolations 12 and the metal grid may be arranged in the first direction and/or the second direction. The first and the second directions may form any angle therebetween. Preferably, the first and the second directions are perpendicular to each other.

The trench isolations 12 and/or the metal grid may have any shape in a transverse cross-section parallel or perpendicular to the first surface of the first substrate 11. Examples of the shape may include, but are not limited to, quadrilateral, hexagonal, octagonal and circular shapes.

For example, the trench isolations 12 and the metal grid may have a quadrilateral shape in a transverse cross-section parallel to the first surface of the first substrate 11. In this case, the trench isolations 12 and the metal grid may be both arranged in the first and second directions into arrays. Adjacent trench isolations 12 arranged in the first direction may cross adjacent trench isolations 12 arranged in the second direction to define an array of quadrilateral cells. Adjacent features of the metal grid arranged in the first direction may cross adjacent features of the metal grid arranged in the second direction to also define an array of quadrilateral cells. Devices may be formed in the first substrate 11 within these quadrilateral cells, such as avalanche diodes or single-photon avalanche diodes (SPADs). FIGS. 1 and 2 schematically illustrate one complete cell defined by four surrounding trench isolations 12, which has a square shape in a transverse cross-section parallel to the first surface of the first substrate 11 and one complete cell defined by features of the metal grid in four surrounding second openings 15 (the metal grid outside the second openings 15 is omitted), which has a square shape in a transverse cross-section parallel to the first surface of the first substrate 11. The square cell defined by the four surrounding trench isolations 12 is aligned with the square cell defined by the features of the metal grid in the four surrounding second openings 15. The cell defined by the four surrounding trench isolations 12 provides a pixel cell. The trench isolations 12 and the metal grid extend in the aforementioned directions to define arrays of such square cells.

In the embodiment of FIGS. 3 to 5, in the first substrate 11 may be formed shallow trench isolations 113 extending from the second surface of the first substrate 11 into the first substrate 11. The shallow trench isolations 113 may be aligned with the trench isolations 12. In one embodiment, the shallow trench isolations 113 may be in contact with the trench isolations 12 so that they together provide isolation between the individual pixel cells. In other embodiments, no shallow trench isolations 113 may be formed in the first substrate 11, and the trench isolations 12 may instead extend from the first surface of the first substrate 11 to the second surface thereof. That is, the trench isolations 12 also provide isolation between the pixel cells.

Avalanche diodes or SPADs may be formed in the first substrate 11 partitioned by the shallow trench isolations 113 and the trench isolations 12. An avalanche diode or SPAD may be formed in each pixel cell.

The pixel cells are surrounded by the trench isolations 12, and the metal grid is formed on the trench isolations 12 and electrically connected to the first conductive layer 122. Moreover, the trench isolations 12 are electrically connected to the metal grid within and outside the second openings 15. Therefore, the pixel cells are fully isolated without optical crosstalk between them.

The third openings 16 may include trenches 161 and first holes 162. The trenches 161 may be situated in the second insulating dielectric layer 13, or in the second insulating dielectric layer 13 and part of the first substrate 11, so that the first substrate 11 is exposed therein. The trenches 161, the first openings 14 and the second openings 15 may be formed in a single process, providing process simplification and cost savings. The first holes 162 may extend from bottom surfaces of the trenches 161 through the first substrate 11.

In one embodiment, the third openings 16 may further include second holes 163 formed in the first interlayer dielectric layer 111 at the bottom of the first holes 162. The first metal interconnects 112 may be exposed in the second holes 163.

The electrical leading-out structure is electrically connected to the first metal interconnects 112 and may be insulated from the first substrate 11 by a third insulating dielectric layer 18 lining inner wall surfaces of the trenches 161 and the first holes 162.

The third insulating dielectric layer 18 may be any electrically insulating material known in the art. For example, it may include at least one of silicon oxide and high-k dielectrics with a dielectric constant (k) greater than 3.9.

Since the second conductive layer 17 is filled in all the first openings 14, the second openings 15 and the third openings 16, the first electrodes, the metal grid and the electrical leading-out structure may be formed using a single filling process, providing simplification and cost savings.

On the electrical leading-out structure may be formed pads 19 electrically connected to the electrical leading-out structure.

The first conductive layer 122, the second conductive layer 17 or the pads 19 may be any conductive metal or non-metal material known in the art. Examples of the material may include, but are not limited to, copper, silver, gold, aluminum, tungsten and nickel. The pads 19 are preferably made of aluminum. Preferably, the first conductive layer 122 and the second conductive layer 17 may be made of the same material, such as tungsten.

In case of the material of the first conductive layer 122 and the second conductive layer 17 (i.e., the aforementioned conductive material) including tungsten, which possesses better hole-filling properties than aluminum, even when the deep trenches 120, the first openings 14, the second openings 15 and the third openings 16 have very large depth-to-width ratios (i.e., when they have very small widths), the conductive material can fully fill them without voids therein. This can avoid open circuit and electrical connection issues, reducing chip size limitations and enabling use in even smaller chips.

Since the conductive material can fill up the first openings 14 and the second openings 15 even when these openings have very small widths, significant width shrinkage of the first openings 14 and the second openings 15 can be achieved. Moreover, as the width W2 of the second openings 15 is less than the width W1 of the deep trenches 120, width shrinkage of the second openings 15 enables corresponding width shrinkage of the trench isolations 12, which allows the pixel cells to be made bigger. Moreover, width shrinkage of the first openings 14 means reductions in areas of the pixel cells shielded by the first electrodes in the first openings 14, increasing incidence of light. In this way, the pixel cells can have greater light absorption areas, which can enhance the photon detection efficiency of the devices. In addition, optical paths therein will be less affected, in particular at a chip size reduced to 5 μm or less.

Further, since the projection of the metal grid within and/or outside the second openings 15 on the first surface of the first substrate 11 is encompassed by the projections of the trench isolations 12 on the first surface of the first substrate 11, significant width shrinkage of the trench isolations 12 enables corresponding width shrinkage of the metal grid. In this way, areas of the pixel cells shielded by the metal grid can be reduced, additionally increasing incidence of light and further enhancing the photon detection efficiency of the devices.

In one embodiment, filling the first openings 14 and the second openings 15 with tungsten in place of aluminum allows the width of the first openings 14 to be reduced from 0.65 μm to 0.2-0.45 μm and allows the width of the metal grid to be reduced from 1.25 μm to 0.15-0.5 μm.

Furthermore, tungsten reflects less light than aluminum, so replacing aluminum with tungsten can further reduce adverse influence on the photon detection efficiency.

Second electrodes (not shown) may be formed on the second surface of the first substrate 11. In case of the first substrate 11 being bonded to the second substrate 21 at the second surface, the second electrodes may be provided on the first surface of the second substrate 21.

To sum up, the present invention provides a semiconductor device including: a substrate having opposing first and second surfaces; trench isolations extending from the first surface of the substrate into the substrate, each of the trench isolations including a first conductive layer insulated from the substrate; an insulating dielectric layer formed on the first surface of the substrate and the trench isolations; first openings, second openings and third openings, the first and second openings situated in the insulating dielectric layer, the first openings exposing the substrate, the second openings exposing the first conductive layer in the trench isolations, the third openings extending through the substrate; and a second conductive layer filling the first, second and third openings and extending outside the second openings, the second conductive layer that fills the first openings providing first electrodes, the second conductive layer that fills the second openings and extends outside the second openings providing a metal grid, the second conductive layer that fills the third openings providing an electrical leading-out structure. The semiconductor device of the present invention can provide higher reliability and optical performance.

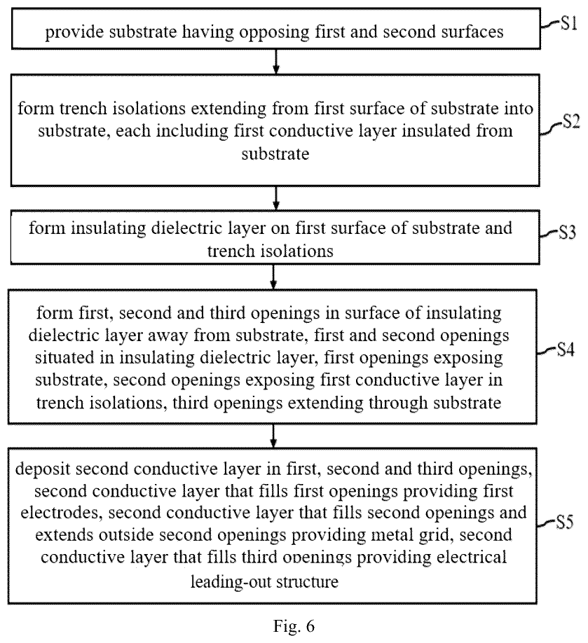

An embodiment of the present invention provides a method of fabricating a semiconductor device. FIG. 6 is a flowchart of the method according to the embodiment.

As shown, the method includes the steps of:
S1) providing a substrate having opposing first and second surfaces;
S2) forming trench isolations extending from the first surface of the substrate into the substrate, each of the trench isolations including a first conductive layer insulated from the substrate;
S3) forming an insulating dielectric layer on the first surface of the substrate and the trench isolations;
S4) forming first, second and third openings in a surface of the insulating dielectric layer away from the substrate, the first and second openings situated in the insulating dielectric layer, the first openings exposing the substrate, the second openings exposing the first conductive layer in the trench isolations, the third openings extending through the substrate; and
S5) depositing a second conductive layer in the first, second and third openings, the second conductive layer that fills the first openings providing first electrodes, the second conductive layer that fills the second openings and extends outside the second openings providing a metal grid, the second conductive layer that fills the third openings providing an electrical leading-out structure.

The method of this embodiment will be described in greater detail below with reference to FIGS. 1 to 5. FIGS. 1 and 2 are schematic partial views of the semiconductor device. As a non-limiting example, the embodiments shown in FIGS. 1 to 5 are described in the context of use in an image sensor of a 3D IC.

In step S1, a substrate is provided (referred to hereinafter as the first substrate 11, in order to be distinguished from the second substrate). The first substrate 11 has opposing first and second surfaces.

A first interlayer dielectric layer 111 may be formed on the second surface of the first substrate 11. In the first interlayer dielectric layer 111 may be formed first metal interconnects 112, as well as other functional structures such as transistors or MEMS's (e.g., diaphragms, electrodes, etc.) Thus, a device wafer is provided. The type of the device wafer may depend on the functionality of the device being fabricated. Alternatively, the first substrate 11 may be a die obtained by dicing such a wafer, without limiting the present application in any sense.

In one embodiment, before the subsequent formation of trench isolations 12 in the first substrate 11, the method may further include: at first, bonding the first substrate 11 at the second surface to a second substrate 21; and then thinning the first substrate 111 to a desired thickness from the side of the first surface.

The second substrate 21 may include opposing first and second surfaces. A second interlayer dielectric layer 22 may be formed on the second surface of the second substrate 21, and second metal interconnects 221 may be formed in the second interlayer dielectric layer 22. The side of the first interlayer dielectric layer 111 away from the first substrate 11 may be bonded to the side of the second interlayer dielectric layer 22 away from the second substrate 21 so that the first metal interconnects 112 are electrically connected to the second metal interconnects 221. The second interlayer dielectric layer 22 may also contain other functional structures, such as transistors or MEMS's (e.g., diaphragms, electrodes, etc.) Thus, another device wafer is provided. The type of the device wafer may depend on the functionality of the device being fabricated. Alternatively, the second interlayer dielectric layer 22 may not contain any functional structures, and may serve as a carrier wafer without any device functions. Still alternatively, the second substrate 21 may be a die obtained by dicing such a wafer, without limiting the present application in any sense.

The first surface(s) of the first substrate 11 and/or the second substrate 21 may be defined as its/their backside(s), and the second surface(s) as front side(s). Alternatively, the first surface(s) of the first substrate 11 and/or the second substrate 21 may be defined as its/their front side(s), and the second surface(s) as backside(s).

The first substrate 11 and/or the second substrate 21 may be fabricated from any suitable substrate material known to those skilled in the art, such as glass, ceramic, a semiconductor material or the like. It may be at least one of the following materials: silicon, germanium, silicon germanium, silicon carbide, silicon germanium carbide, indium arsenide, gallium arsenide and indium phosphide. Alternatively, the first substrate 11 and the second substrate 21 may be SOI substrates.

In step S2, trench isolations 12 are formed, which extend from the first surface of the substrate 11 into the substrate 11 and each include a first conductive layer 122 insulated from the substrate 11.

The first conductive layer 122 may be insulated from the first substrate 11 by a first insulating dielectric layer 121.

The trench isolations 12 may be formed using a process including the steps of: first of all, forming deep trenches 120 in the first substrate 11, which extend from the first surface of the first substrate 11 into the first substrate 11; subsequently, forming the first insulating dielectric layer 121 on inner wall surfaces of the deep trenches 120; and then filling the first conductive layer 122 in the deep trenches 120.

Top surfaces of the trench isolations 12 may be flush with the first surface of the first substrate 11 (as shown in FIGS. 3 to 5). Alternatively, the top surfaces of the trench isolations 12 may be higher or lower than the first surface of the first substrate 11. The first insulating dielectric layer 121 may also extend on the first surface of the first substrate 11.

In step S3, an insulating dielectric layer is formed on the first surface of the substrate and the trench isolations (referred to hereinafter as the second insulating dielectric layer 13, in order to be distinguished from the first insulating dielectric layer 121).

The first insulating dielectric layer 121 and/or the second insulating dielectric layer 13 may each be any electrically insulating material known in the art. For example, it may include at least one of silicon oxide and high-k dielectrics with a dielectric constant (k) greater than 3.9. The first insulating dielectric layer 121 and/or the second insulating dielectric layer 13 may each be a single layer or a stack of at least two layers (e.g., one silicon oxide layer and one high-k dielectric layer). Other material(s) may also be present between the first insulating dielectric layer 121 and/or the second insulating dielectric layer 13 and the first substrate 11.

A high-k dielectric can enable the first insulating dielectric layer 121 to provide enhanced insulation.

In step S4, first openings 14, second openings 15 and third openings 16 are formed in a surface of the second insulating dielectric layer 13 away from the substrate 11. The first openings 14 and the second openings 15 are situated in the second insulating dielectric layer 13. The first substrate 11 is exposed in the first openings 14, and the first conductive layer 122 in the trench isolations 12 is exposed in the second openings 15. The third openings 16 extend through the second insulating dielectric layer 13 and the first substrate 11.

Preferably, the deep trenches 120, the first openings 14 and the second openings 15 may be located in a pixel area, and the third openings 16 may be located in a peripheral area which is peripheral to the pixel area. The third openings 16 are not shown in the schematic diagrams of FIGS. 1 and 2.

The first openings 14, the second openings 15 and the third openings 16 may also extend through any material between the second insulating dielectric layer 13 and the first surface of the first substrate 11, if present. For example, the first insulating dielectric layer 121 may be formed on the first surface of the first substrate 11 and the second insulating dielectric layer 13 in turn on the first insulating dielectric layer 121. In this case, the first openings 14, the second openings 15 and the third openings 16 may also extend through the first insulating dielectric layer 121.

The third openings 16 may include trenches 161 and first holes 162. The trenches 161 may be situated in the second insulating dielectric layer 13, or in the second insulating dielectric layer 13 and part of the first substrate 11, so that the first substrate 11 is exposed therein. The trenches 161, the first openings 14 and the second openings 15 may be formed in a single process, providing process simplification and cost savings. The first holes 162 may extend from bottom surfaces of the trenches 161 through the first substrate 11.

In one embodiment, the third openings 16 may further include second holes 163 formed in the first interlayer dielectric layer 111 at the bottom of the first holes 162. The first metal interconnects 112 may be exposed in the second holes 163.

In step S5, a second conductive layer 17 is deposited in the first openings 14, the second openings 15 and the third openings 16. The second conductive layer 17 that fills the first openings 14 provides first electrodes. The second conductive layer 17 that fills the second openings 15 and extends outside the second openings 15 provides a metal grid. The second conductive layer 17 that fills the third openings provides an electrical leading-out structure.

In other embodiments, in addition to filling the first openings 14, the second conductive layer 17 may also extend outside the first openings 14.

The second conductive layer 17 may be formed using a process including the steps of: first of all, depositing a conductive material in the first openings 14, the second openings 15 and the third openings 16 and on a surface of the second insulating dielectric layer 13; and removing part of the conductive material deposited above the surface of second insulating dielectric layer 13 using a patterning process, with the conductive material in the first openings 14, the second openings 15 and the third openings 16 and above the second openings 15 being retained as the second conductive layer 17. In other embodiments, the conductive material above the first openings 14 may also be retained.

Since the second conductive layer 17 is filled in all the first openings 14, the second openings 15 and the third openings 16, the first electrodes, the metal grid and the electrical leading-out structure may be formed using a single filling process, providing simplification and cost savings.

The electrical leading-out structure are electrically connected to the first metal interconnects 112 and may be insulated from the first substrate 11 by a third insulating dielectric layer 18 lining inner wall surfaces of the trenches 161 and the first holes 162.

The third insulating dielectric layer 18 may be any electrically insulating material known in the art. For example, it may include at least one of silicon oxide and high-k dielectrics with a dielectric constant (k) greater than 3.9.

The trench isolations 12 may be arranged in both first and second directions into an array. Moreover, the trench isolations 12 arranged in the first direction may cross the trench isolations 12 arranged in the second direction at intersections.

As shown in FIGS. 1 and 3, the first electrodes may be located at corners of the intersections. Additionally, the first openings 14 may be isolated from the second openings 15 by the second insulating dielectric layer 13, and the first electrodes may be electrically connected to the first substrate 11 and the metal grid to the first conductive layer 122 in the trench isolations 12. Alternatively, as shown in FIGS. 2 and 4, with the first electrodes being located at corners of the intersections, the first openings 14 may be brought into communication with the second openings 15, and the first electrodes and the metal grid may be both electrically connected to both the first substrate 11 and the first conductive layer 122.

The metal grid may be arranged in the first and second directions into an array. A projection of the metal grid within or outside the second openings 15 on the first surface of the first substrate 11 may at least partially overlap projections of the trench isolations 12 on the first surface of the first substrate 11. Preferably, the projection of the metal grid within and/or outside the second openings 15 on the first surface of the first substrate 11 may be encompassed by the projections of the trench isolations 12 on the first surface of the first substrate 11. In particular, in a cross-section perpendicular to the first surface of the first substrate 11, the deep trenches 120 may have a width W1, the second openings 15 may have a width W2, and the metal grid outside the second openings 15 may have a width W3 (not shown). Additionally, W2 or W3 may be not greater than W1, i.e., W3≤W1 or W2≤W1. In other embodiments, W2 or W3 may be greater than W1.

Devices may be formed in the first substrate 11 surrounded by adjacent trench isolations 12 arranged in the first direction and adjacent trench isolations 12 arranged in the second direction. The adjacent two trench isolations 12 arranged in the first direction and the adjacent two trench isolations 12 arranged in the second direction may delimit a region having any shape in a transverse cross-section parallel to the first surface of the first substrate 11. Examples of the shape may include, but are not limited to, quadrilateral, hexagonal, octagonal and circular shapes.

The first openings 14 and/or the second openings 15 may have any shape in a transverse cross-section parallel or perpendicular to the first surface of the first substrate 11. Examples of the shape may include, but are not limited to, quadrilateral, hexagonal, octagonal and circular shapes.

The trench isolations 12 and the metal grid may be arranged in the first direction and/or the second direction. The first and the second directions may form any angle therebetween. Preferably, the first and the second directions are perpendicular to each other.

The trench isolations 12 and/or the metal grid may have any shape in a transverse cross-section parallel or perpendicular to the first surface of the first substrate 11. Examples of the shape may include, but are not limited to, quadrilateral, hexagonal, octagonal and circular shapes.

For example, the trench isolations 12 and the metal grid may have a quadrilateral shape in a transverse cross-section parallel to the first surface of the first substrate 11. In this case, the trench isolations 12 and the metal grid may be both arranged in the first and second directions into arrays. Adjacent trench isolations 12 arranged in the first direction may cross adjacent trench isolations 12 arranged in the second direction to define an array of quadrilateral cells. Adjacent features of the metal grid arranged in the first direction may cross adjacent features of the metal grid arranged in the second direction to also define an array of quadrilateral cells. Devices may be formed in the first substrate 11 within these quadrilateral cells, such as avalanche diodes or SPADs. FIGS. 1 and 2 schematically illustrate one complete cell defined by four surrounding trench isolations 12, which has a square shape in a transverse cross-section parallel to the first surface of the first substrate 11 and one complete cell defined by features of the metal grid in four surrounding second openings 15 (the metal grid outside the second openings 15 is omitted), which has a square shape in a transverse cross-section parallel to the first surface of the first substrate 11. The square cell defined by the four surrounding trench isolations 12 is aligned with the square cell defined by the features of the metal grid in the four surrounding second openings 15. The cell defined by the four surrounding trench isolations 12 provides a pixel cell. The trench isolations 12 and the metal grid extend in the aforementioned directions to define arrays of such square cells.

In the embodiment of FIGS. 3 to 5, in the first substrate 11 may be formed shallow trench isolations 113 extending from the second surface of the first substrate 11 into the first substrate 11. The shallow trench isolations 113 may be aligned with the trench isolations 12. In one embodiment, the shallow trench isolations 113 may be in contact with the trench isolations 12 so that they together provide isolation between the individual pixel cells. In other embodiments, no shallow trench isolations 113 may be formed in the first substrate 11, and the trench isolations 12 may instead extend from the first surface of the first substrate 11 to the second surface thereof. That is, the trench isolations 12 also provide isolation between the pixel cells.

Avalanche diodes or SPADs may be formed in the first substrate 11 partitioned by the shallow trench isolations 113 and the trench isolations 12. An avalanche diode or SPAD may be formed in each pixel cell.

The pixel cells are surrounded by the trench isolations 12, and the metal grid is formed on the trench isolations 12 and electrically connected to the first conductive layer 122. Moreover, the trench isolations 12 are electrically connected to the metal grid within and outside the second openings 15. Therefore, the pixel cells are fully isolated without optical crosstalk between them.

After the second conductive layer 17 is formed, the method may further include: forming pads 19 on the electrical leading-out structure, which are electrically connected to the electrical leading-out structure.

The first conductive layer 122, the second conductive layer 17 or the pads 19 may be any conductive metal or non-metal material known in the art. Examples of the material may include, but are not limited to, copper, silver, gold, aluminum, tungsten and nickel. The pads 19 are preferably made of aluminum. Preferably, the first conductive layer 122 and the second conductive layer 17 may be made of the same material, such as tungsten.

In case of the material of the first conductive layer 122 and the second conductive layer 17 (i.e., the aforementioned conductive material) including tungsten, which possesses better hole-filling properties than aluminum, even when the deep trenches 120, the first openings 14, the second openings 15 and the third openings 16 have very large depth-to-width ratios (i.e., when they have very small widths), the conductive material can fully fill them without voids therein. This can avoid open circuit and electrical connection issues, reducing chip size limitations and enabling use in even smaller chips.

Since the conductive material can fill up the first openings 14 and the second openings 15 even when these openings have very small widths, significant width shrinkage of the first openings 14 and the second openings 15 can be achieved. Moreover, as the width W2 of the second openings 15 is less than the width W1 of the deep trenches 120, width shrinkage of the second openings 15 enables corresponding width shrinkage of the trench isolations 12, which allows the pixel cells to be made bigger. Moreover, width shrinkage of the first openings 14 means reductions in areas of the pixel cells shielded by the first electrodes in the first openings 14, increasing incidence of light. In this way, the pixel cells can have greater light absorption areas, which can enhance the photon detection efficiency of the devices. In addition, optical paths therein will be less affected, in particular at a chip size reduced to 5 μm or less.

Further, since the projection of the metal grid within and/or outside the second openings 15 on the first surface of the first substrate 11 is encompassed by the projections of the trench isolations 12 on the first surface of the first substrate 11, significant width shrinkage of the trench isolations 12 enables corresponding width shrinkage of the metal grid. In this way, areas of the pixel cells shielded by the metal grid can be reduced, additionally increasing incidence of light and further enhancing the photon detection efficiency of the devices.

In one embodiment, filling the first openings 14 and the second openings 15 with tungsten in place of aluminum allows the width of the first openings 14 to be reduced from 0.65 μm to 0.2-0.45 μm and allows the width of the metal grid to be reduced from 1.25 μm to 0.15-0.5 μm.

Furthermore, tungsten reflects less light than aluminum, so replacing aluminum with tungsten can further reduce adverse influence on the photon detection efficiency.

Second electrodes (not shown) may be formed on the second surface of the first substrate 11. In case of the first substrate 11 being bonded to the second substrate 21 at the second surface, the second electrodes may be provided on the first surface of the second substrate 21.

In summary, the present invention provides a method of fabricating a semiconductor device, which includes: providing a substrate having opposing first and second surfaces; forming trench isolations extending from the first surface of the substrate into the substrate, each of the trench isolations including a first conductive layer insulated from the substrate; forming an insulating dielectric layer on the first surface of the substrate and the trench isolations; forming first, second and third openings in a surface of the insulating dielectric layer away from the substrate, the first and second openings situated in the insulating dielectric layer, the first openings exposing the substrate, the second openings exposing the first conductive layer in the trench isolations, the third openings extending through the substrate; and depositing a second conductive layer in the first, second and third openings, the second conductive layer that fills the first openings providing first electrodes, the second conductive layer that fills the second openings and extends outside the second openings providing a metal grid, the second conductive layer that fills the third openings providing an electrical leading-out structure. A semiconductor device with improved reliability and optical performance is obtainable according to this method.

The description presented above is merely that of a few preferred embodiments of the present invention and does not limit the scope thereof in any sense. Any and all changes and modifications made by those of ordinary skill in the art based on the above teachings fall within the scope as defined in the appended claims.

1. A semiconductor device, comprising:
a substrate having a first surface and a second surface opposite to the first surface;
trench isolations extending from the first surface of the substrate into the substrate, each of the trench isolations comprising a first conductive layer insulated from the substrate;
an insulating dielectric layer formed on the first surface of the substrate and the trench isolations;
first openings, second openings and third openings, the first openings and the second openings formed in the insulating dielectric layer, the first openings exposing the substrate, the second openings exposing the first conductive layer in the trench isolations, the third openings extending through the substrate; and
a second conductive layer, the second conductive layer that fills the first openings providing first electrodes, the second conductive layer that fills the second openings and extends outside the second openings providing a metal grid, the second conductive layer that fills the third openings providing an electrical leading-out structure.

2. The semiconductor device of claim 1, wherein the trench isolations are arranged in a first direction and a second direction into an array, wherein the trench isolations arranged in the first direction cross the trench isolations arranged in the second direction at intersections, and wherein each of the intersections is provided at its four corners with respective ones of the first electrodes.

3. The semiconductor device of claim 1, wherein the metal grid is arranged in a first direction and a second direction into an array, wherein a projection of the metal grid within and/or outside the second openings on the first surface of the substrate at least partially overlaps projections of the trench isolations on the first surface of the substrate.

4. The semiconductor device of claim 3, wherein the projection of the metal grid within and/or outside the second openings on the first surface of the substrate is encompassed by the projections of the trench isolations on the first surface of the substrate.

5. The semiconductor device of claim 1, wherein the first conductive layer is made of the same material as the second conductive layer.

6. The semiconductor device of claim 1, wherein second electrodes are formed on the second surface of the substrate.

7. The semiconductor device of claim 1, wherein the first electrodes are electrically connected to the substrate and the metal grid is electrically connected to the first conductive layer in the trench isolations.

8. The semiconductor device of claim 1, wherein the first openings are isolated from the second openings by the insulating dielectric layer.

9. The semiconductor device of claim 1, wherein the first openings are brought into communication with the second openings, and the first electrodes and the metal grid are both electrically connected to both the substrate and the first conductive layer.

10. The semiconductor device of claim 1, wherein the third openings comprise trenches and first holes, and wherein the first openings, the second openings and the trenches are formed in a single process.

11. A method of fabricating a semiconductor device, comprising:
providing a substrate having a first surface and a second surface opposite to the first surface;
forming trench isolations extending from the first surface of the substrate into the substrate, each of the trench isolations comprising a first conductive layer insulated from the substrate;
forming an insulating dielectric layer on the first surface of the substrate and the trench isolations;
forming first openings, second openings and third openings in a surface of the insulating dielectric layer away from the substrate, the first openings and the second openings formed in the insulating dielectric layer, the first openings exposing the substrate, the second openings exposing the first conductive layer in the trench isolations, the third openings extending through the substrate; and
depositing a second conductive layer in the first, second and third openings, the second conductive layer that fills the first openings providing first electrodes, the second conductive layer that fills the second openings and extends outside the second openings providing a metal grid, the second conductive layer that fills the third openings providing an electrical leading-out structure.

12. The method of claim 11, wherein the second conductive layer is formed using a process comprising:
forming a conductive material in the first, second and third openings and on a surface of the insulating dielectric layer; and
removing part of the conductive material above the surface of the insulating dielectric layer by patterning, with the conductive material in the first, second and third openings and above the second openings being retained as the second conductive layer.

13. The method of claim 11, further comprising, after the second conductive layer is formed,
forming pads on the electrical leading-out structure, which are electrically connected to the electrical leading-out structure.

14. The method of claim 11, wherein the third openings comprise trenches and first holes, and wherein the first openings, the second openings and the trenches are formed in a single process.

15. The method of claim 11, wherein the trench isolations are arranged in a first direction and a second direction into an array, wherein the trench isolations arranged in the first direction cross the trench isolations arranged in the second direction at intersections, and wherein each of the intersections is provided at its four corners with respective ones of the first electrodes.

16. The method of claim 11, wherein the metal grid is arranged in a first direction and a second direction into an array, wherein a projection of the metal grid within and/or outside the second openings on the first surface of the substrate at least partially overlaps projections of the trench isolations on the first surface of the substrate.

17. The method of claim 16, wherein the projection of the metal grid within and/or outside the second openings on the first surface of the substrate is encompassed by the projections of the trench isolations on the first surface of the substrate.

18. The method of claim 11, wherein the first conductive layer is made of the same material as the second conductive layer.

19. The method of claim 11, wherein the first openings are isolated from the second openings by the insulating dielectric layer, and the first electrodes are electrically connected to the substrate and the metal grid is electrically connected to the first conductive layer in the trench isolations.

20. The method of claim 11, wherein the first openings are brought into communication with the second openings, and the first electrodes and the metal grid are both electrically connected to both the substrate and the first conductive layer.
